(19) United States
(12) Patent Application Publication
(10) Pub. No.: US 2024/0167177 A1
(43) Pub. Date: May 23, 2024

(54) BIPOLAR PLATE AND METHOD FOR PRODUCING SAME

(71) Applicant: Reinz-Dichtungs-GmbH, Neu-Ulm (DE)

(72) Inventors: Edda GALLMEIER, Neu-Ulm (DE); Lisa JERG, Neu-Ulm (DE); Nadine LIEBHABER, Weissenhorn (DE); Sebastian SCHEELER, Stuttgart (DE); Felix SENF, Ulm (DE); Stephan WENZEL, Pfaffenhofen (DE)

(21) Appl. No.: 18/511,792

(22) Filed: Nov. 16, 2023

(30) Foreign Application Priority Data
Nov. 17, 2022 (DE) 10 2022 212 251.8

(51) Int. Cl. C25B 11/036; C23C 14/16; C23C 14/34; C25B 11/04

(52) U.S. Cl. CPC C25B 11/036; C23C 14/165; C23C 14/34; C25B 11/04; H01M 8/0228

(57) ABSTRACT

A bipolar plate and method for producing a bipolar plate for an electrochemical system, comprising a core layer, which comprises a steel material and a metal anti-corrosion layer that protects the core layer from corrosion. The anti-corrosion layer comprises a plurality of anti-corrosion layer coats that comprise a substantially identical anti-corrosion material and are arranged one on top of the other. A material density of the anti-corrosion material within an anti-corrosion layer coat has a gradient as the distance from the core layer increases.

### CROSS-REFERENCE TO RELATED APPLICATION

The present application claims priority to German Patent Application No. 10 2022 212 251.8, entitled “BIPOLAR PLATE AND METHOD FOR PRODUCING SAME”, and filed Nov. 17, 2022. The entire contents of the above-listed application is hereby incorporated by reference for all purposes.

### TECHNICAL FIELD

The disclosure relates to a bipolar plate for an electrochemical system such as an electrolyzer and/or a fuel cell and/or a redox flow battery, comprising a core layer that consists of a steel material and is equipped with a metal anti-corrosion layer that protects the core layer from corrosion caused by an electrolyte of the electrochemical system, and to a method for producing a bipolar plate of this kind.

### BACKGROUND AND SUMMARY

In electrochemical systems such as electrolyzers or fuel cells and redox flow batteries, the components involved, such as the bipolar plates used, have to be protected from corrosion caused by the chemical substances involved, in order to enable a long service life of the system.

In this regard, for example, DE 10 2007 032 116 A1 discloses a bipolar plate for a fuel cell, which bipolar plate may be produced cost-effectively and in which high efficiency is guaranteed over a long period of use. For this purpose, the bipolar plate has a core layer that consists of a steel material and the surfaces of which assigned to the relevant electrolyte carrier of the fuel cell are each equipped with an anti-corrosion layer that protects the core layer from corrosion. In this case, the anti-corrosion layers each consist of a metal material, and each extend over the core layer in its entirety on both sides. At the same time, the anti-corrosion layers in turn are each entirely coated with an electrically conductive functional coat that is substantially completely impermeable to metal ions emerging from the core layer and/or the anti-corrosion layers.

DE 10 2020 130 695 A1 relates to a component of an electrochemical cell, comprising a metal substrate, a metal first coat applied to the metal substrate at least in part, and a second coat applied to the first coat, the metal first coat having a layer thickness of at least 3 μm and predominantly comprising at least one metal of the group comprising titanium, niobium, hafnium, zirconium, tantalum, magnesium, silver, nickel and tungsten. The second coat can be selected from three different cover layers. The electrochemical cell can be in the form of a redox flow cell, a fuel cell or an electrolyzer.

Therefore, the object of the present disclosure is to better protect components, such as bipolar plates, for an electrochemical system from corrosion while not impairing the conductivity of the components.

This object is achieved by the subject matter of the independent claims. Further embodiments are set out in the dependent claims, the description and the drawings.

One aspect relates to a bipolar plate for an electrochemical system, for example for an electrolyzer and/or for a fuel cell and/or for a redox flow battery. The bipolar plate has a core layer, which consists of or comprises a steel material and is equipped with a metal anti-corrosion layer that protects the core layer from corrosion that may be caused by an electrolyte of the electrochemical system. The steel material of the core layer can be a stainless steel or can comprise stainless steel.

The anti-corrosion layer has a plurality of, e.g. at least two or more than two, anti-corrosion layers coats, which may also referred to as coatings, that consist of or comprises a substantially identical anti-corrosion material and are arranged one on top of the other (and thus one above the other in a normal direction perpendicular to a main extension plane of the core layer). A substantially identical anti-corrosion material can in each case be an identical anti-corrosion material, for example a metal, or also a substantially identical anti-corrosion material, for example metal compounds, which may vary slightly in terms of their composition, e.g. are so similar or constant in terms of their composition that each composition is functionally the same when the bipolar plate is used as intended. One example of a pure metal is titanium (Ti); one example of a metal compound is titanium nitride (TiN). The anti-corrosion material of the anti-corrosion layer accordingly can be titanium or be substantially titanium or comprise titanium. Effective protection can be achieved in this way.

In this case, a material density of the anti-corrosion material within an anti-corrosion layer coat, for instance within each of the anti-corrosion layer coats, has a gradient over the entirety of the respective layer coat as the distance from the core layer increases. In this regard, the gradient can refer to a material density that increases as the distance from the core layer increases and/or a material density that decreases as the distance from the core layer increases. In this case, the gradient can have a predetermined minimum gradient, which can be stated in percentage terms, for example. An example minimum gradient can thus be 0.5-20% per anti-corrosion layer coat, e.g. a 0.5-20% increase or decrease in the material density per anti-corrosion layer coat. It is also possible for the material density to change abruptly at each transition from anti-corrosion layer coat to anti-corrosion layer coat. For example, a material density at the transitions can have a gradient that actually runs in the opposite direction to the gradient within each anti-corrosion layer coat. In this case, the gradient at the transitions may be greater in terms of magnitude than the gradient within a coat, for example greater by one or more orders of magnitude.

The advantage of the material density gradient is that permeability of the anti-corrosion layer coats to substances such as the electrolytes is reduced, since a density of the anti-corrosion layer is optimized at least in parts of each anti-corrosion layer coat, e.g. denser packing of the anti-corrosion material and additionally, where applicable, improved adhesion to the core layer are achieved, both of which result in an anti-corrosion layer that is less easily penetrated and thus in improved protection against corrosion.

In a further embodiment, the anti-corrosion layer coats have a minimum layer thickness of at least 15 nm, at least 20 nm, at least 40 nm, at least 50 nm, at least 60 nm, or at least 70 nm. Accordingly, the anti-corrosion layer coats can have a maximum layer thickness of at most 300 nm, at most 200 nm, at most 100 nm, at most 75 nm, or at most 70 nm. Here, reference is made to minimum and maximum layer thicknesses since such coatings typically cannot be generated in an entirely homogeneous manner, and so, depending on the type of coating method, the result for each anti-corrosion layer coat is a slightly varying layer thickness that fluctuates locally between the minimum and maximum layer thickness. However, the regions that deviate from the other regions in terms of their coating properties due to edge or rim effects are not taken into consideration here. Different anti-corrosion layer coats can also have different layer thicknesses, such as different minimum and maximum layer thicknesses, for which different values from those stated may apply in each case. The stated values lead to anti-corrosion layer coats which may be compressed well, e.g. for which a gradient in the material density may be generated effectively.

In a further embodiment, the anti-corrosion layer has a minimum layer thickness of at least 50 nm, at least 100 nm, at least 150 nm, or at least 200 nm. Accordingly, the anti-corrosion layer coat can have a maximum layer thickness of at most 3 μm, at most 2.5 μm, at most 2 μm, at most 1 μm, at most 500 nm, at most 300 nm, or at most 200 nm. The stated thickness ranges in this case may protect the bipolar plate; for instance, in this way a plurality of effective anti-corrosion layer coats can be produced one above the other such that reliable protection against corrosion is achieved even with a relatively low layer thickness.

In a further embodiment, the anti-corrosion layer is impermeable to media (this does not mean electrons) such as hydrogen, oxygen, coolants, such as water-based coolants, or a mixture of said media, for example oxygen-water mixtures. As regards redox flow batteries, it is provided in further embodiments that the anti-corrosion layer is impermeable to electrolyte mixtures that are conceivable for this application; this relates to vanadium-based (aqueous or non-aqueous) solutions such as vanadium chloride, to various metal bromide systems such as zinc bromide, or to systems of other heavy metals such as iron-chromium systems, and to complex organic electrolytes and/or lignin-based electrolytes. Depending on the application, the anti-corrosion layer can thus be configured to be impermeable to, for example: CO₂, (aqueous or non-aqueous) metal salt solutions such as sodium or lithium salts, tetrafluoroethoxy-benzene, methoxy-benzene, 2,2,6,6-tetramethylpiperidinyloxyl (TEMPO), 7,8-dihydroxyphenazine-2-sulfonic acid, potassium hexacyanoferrate (II/III), hydrochloric acid, Fe²⁺/Fe³⁺ solutions, polycyclic aromatic alcohol/ketone redox systems.

Accordingly, the number of anti-corrosion layer coats and the layer thicknesses thereof or the layer thickness of the anti-corrosion layer are then selected such that the electrolyte(s) or the medium is prevented from penetrating the anti-corrosion layer and reaching the core material over the entire life cycle at the temperatures and voltages that occur when the bipolar plate in question is used as intended.

In a further embodiment, the anti-corrosion layer is arranged on a side of the core layer that faces the anode when the bipolar plate is used as intended, and may be only the side of the core layer that faces the anode when the bipolar plate is used as intended has such an anti-corrosion layer. In the latter case, the side of the core layer that faces the cathode when the bipolar plate is used as intended can likewise have a coating, even an anti-corrosion layer, which can then differ from the anti-corrosion layer being described here, which has a plurality of substantially identical anti-corrosion layer coats of varying material densities. The advantage of this is that production of the bipolar plate is simplified since the requirements in terms of protection against corrosion on the anode side may be high. Accordingly, layer-by-layer compressing of the anti-corrosion layer can be limited to the side of the core layer that faces the anode. The anti-corrosion layer can fully cover at least an active region of the side of the bipolar plate that faces the anode, or also fully cover the side of the bipolar plate that faces the anode. The active region is a region which, when the bipolar plate is orthogonally projected into the plane of the electrolyte membrane, overlaps or is congruent with the active surface of the electrolyte membrane, e.g. not with a reinforcement edge or frame that is usually present.

In a further embodiment, the anti-corrosion layer is attached to the core layer directly (or directly without any further layers or coats between the anti-corrosion layer and the core layer). For instance, therefore, a passive coat, for example an oxidized uppermost coat of the core layer, is removed before the coating with the anti-corrosion layer coat such as to improve a chemical and, consequently, a mechanical interplay between the core layer and the first anti-corrosion layer coat and thus the anti-corrosion layer. The advantage of this is improved adhesion. Furthermore, this ensures good conductivity.

In addition, the uppermost anti-corrosion layer coat, e.g. the anti-corrosion layer coat that is furthest away from the core layer, can be chemically modified at least in its regions close to the surface. For example, TiN or TiC can be formed by bombardment with nitrogen or acetylene. Chemical modification of this kind may be ruled out for the anti-corrosion layer coats arranged between the uppermost anti-corrosion layer coat and the core layer.

In a further embodiment, the anti-corrosion layer in turn is equipped with a cover layer, which may be niobium, tantalum, platinum or gold or comprises niobium, tantalum, platinum and/or gold. A cover layer of this kind can prevent the surface of the anti-corrosion layer from degrading. The cover layer can completely cover the anti-corrosion layer. An uppermost anti-corrosion layer coat that is chemically modified at least in part can bring about better adhesion between the cover layer and the anti-corrosion layer and/or better conductivity between said layers.

One aspect also relates to an electrolyzer as an electrochemical system, comprising at least one bipolar plate according to any of the preceding embodiments, such as a multiplicity of bipolar plates according to any of the preceding embodiments. Electrolyzers have particularly high requirements which are placed on the chemical durability of the bipolar plate, and in this respect the improvement to the protection against corrosion described here may be desirable.

A further aspect is a method for producing a bipolar plate for an electrochemical system, for example for an electrolyzer and/or for a fuel cell and/or for a redox flow battery.

Starting from a core layer of the bipolar plate, which core layer consists of or comprises a a steel material, e.g. starting from the uncoated bipolar plate, the bipolar plate is coated n times with an anti-corrosion material using physical vapor deposition, an nth anti-corrosion layer coat being formed in the coating nth method step, where n>1. Thus, the first anti-corrosion layer coat is arranged on the core layer, the second anti-corrosion layer coat is arranged on the first anti-corrosion layer coat, and so on. Between each two coating method steps, the anti-corrosion layer coat formed previously in the relevant coating is bombarded with an inert gas. The inert gas can be or comprise argon. If the bipolar plate has n anti-corrosion layer coats, then at least the n−1 lowermost anti-corrosion layer coats have been bombarded with the gas. Optionally, the last, e.g. the nth, anti-corrosion layer coat, can also be bombarded with the gas after the last, e.g. the nth, coating. In each case, therefore, following the (n−1)th coating method step, for instance following each nth coating method step, the anti-corrosion layer coat formed during the relevant coating is bombarded with an inert gas such that at least the anti-corrosion layer coat(s) closest to the core layer is/are bombarded with the inert gas.

In this case, advantages and further embodiments of the method correspond to the advantages and further embodiments described in relation to the bipolar plate.

In a further embodiment, before the first coating of the core layer, the passive coat of the core layer is removed at least in some portions at least on the side to be coated.

In a further embodiment, each (nth) coating is carried out by cathode sputtering, also referred to as sputtering.

In a further embodiment, before the first coating of the core layer and, where applicable, also before the removal of the passive coat of the core layer, the core layer is deformed (e.g. deformed in advance); for instance, conductor structures such as channels and ridges or ridge portions formed between the channels are molded therein at least in some regions. In addition, after the (nth) coating, or alternatively also after the application of the cover coat, further deformation is carried out and the conductor structures thus may obtain their final shape. As a result of the at least partial deformation that takes place before the coating or sputtering, damage to the coating of the bipolar plate is reduced and the protection against corrosion is thus improved.

The features and feature combinations stated above in the description, including in the introductory part, and the features and feature combinations stated below in the description of the drawings and/or shown separately in the drawings can be used in combinations other than those stated in each case, without departing from the scope of the present disclosure. In this respect, the present disclosure should be considered to include and disclose embodiments that are not explicitly shown in the drawings or explained but which arise and can be produced from the described embodiments as a result of separate feature combinations. Embodiments and feature combinations that consequently do not contain all the features of an original independent claim should also be deemed disclosed. In addition, the present disclosure should be taken to disclose embodiments and feature combinations, such as those resulting from the above-described embodiments, that either go beyond or deviate from the feature combinations presented in the back-references of the claims.

It should be understood that the summary above is provided to introduce in simplified form a selection of concepts that are further described in the detailed description. It is not meant to identify key or essential features of the claimed subject matter, the scope of which is defined uniquely by the claims that follow the detailed description. Furthermore, the claimed subject matter is not limited to implementations that solve any disadvantages noted above or in any part of this disclosure.

The subject matter according to the present disclosure will now be explained in more detail on the basis of the schematic figures shown in the following drawings, but it is not intended to be limited to the specific embodiments shown therein.

### BRIEF DESCRIPTION OF THE FIGURES

FIG. 1A is a sectional view of an example embodiment of an electrolyzer having a multiplicity of bipolar plates.

FIG. 1B is a plan view of a bipolar plate of the electrolyzer from FIG. 1A.

FIG. 2A is a sectional view of a bipolar plate from the prior art having the broad damage thereto.

FIG. 2B is a sectional view of a bipolar plate from the prior art having a global material density gradient over the entire coating.

FIG. 2C is a sectional view of a first example bipolar plate having local material density gradients over individual coats of the coating.

FIG. 2D is a sectional view of a second example bipolar plate having local material density gradients over individual coats of the coating.

FIG. 3 is a flowchart of an example method for producing a bipolar plate.

### DETAILED DESCRIPTION

Like elements or those with identical functions have been provided with the same reference numerals in the drawings.

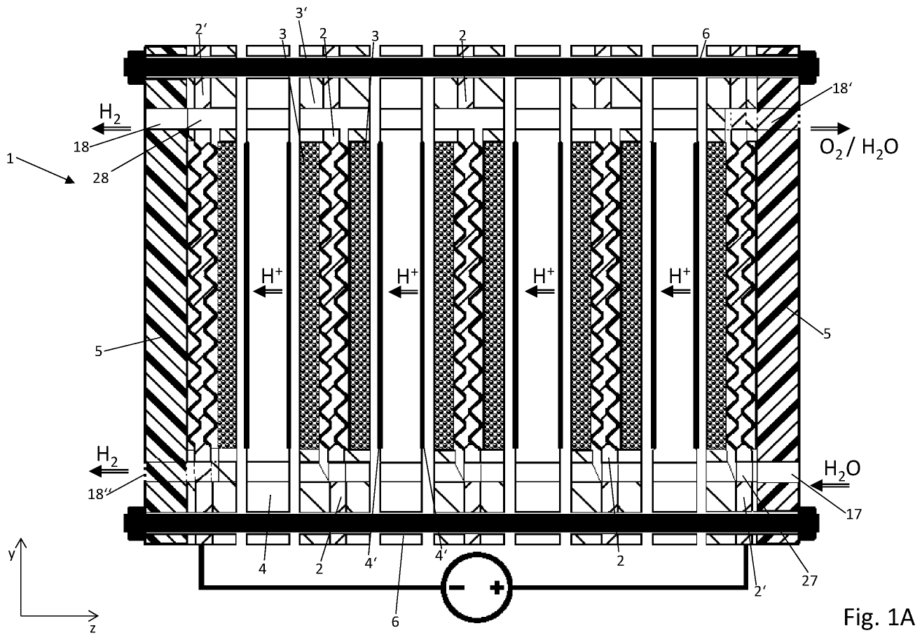

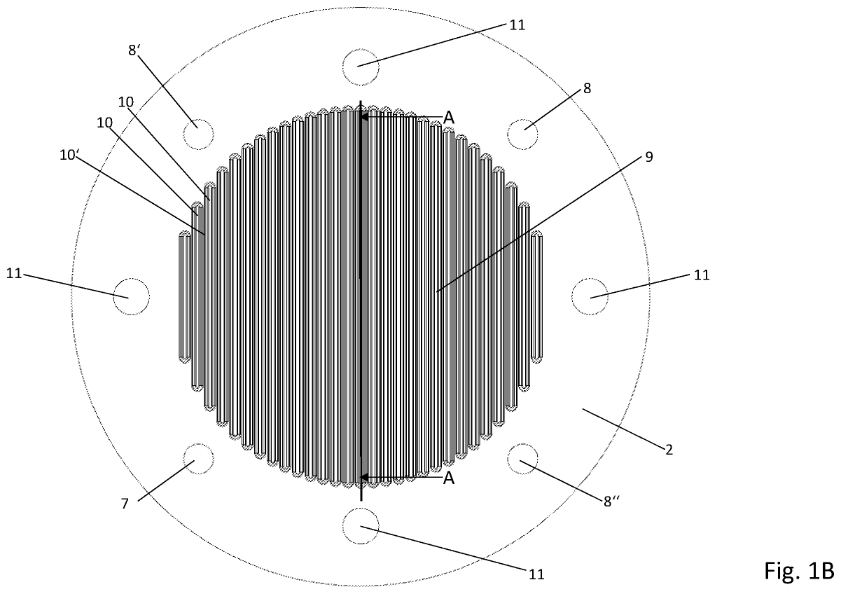

FIG. 1A is a sectional view of an example embodiment of an electrochemical system 1, configured here as an electrolyzer, comprising a multiplicity of (in the present case three) bipolar plates 2 and two bipolar plates used as terminal unipolar plates 2′, which each conduct medium only on one surface but in this case are configured per se having the same features as the other bipolar plates and are thus likewise regarded as bipolar plates in the context of this application. In the present case, between each two closest neighboring bipolar plates 2 or unipolar plates 2′ there are arranged two transport layers 3 having respective frame elements 3′, and a membrane element 4 having respective catalyst coats 4′ is in turn arranged between the two transport layers 3. In this case, bipolar plates 2, transport layers 3 having frame elements 3, and membrane elements 4 are stacked in a z-direction as the stacking direction and are, for example, held together by end plates 5 and bolt elements 6. In the end plates 5 there are formed, as through-openings, an inlet 17 for H₂O, two outlets 18, 18″ for H₂, of which the latter lies outside the sectional plane, and, likewise outside the sectional plane, an outlet 18′ for O₂ and H₂O. For clarity, FIG. 1 shows the membrane elements 4, on the one hand, and the bipolar plates 2 comprising the transport layers 3 and frame elements 3′, on the other hand, at a distance from one another. In actual fact, said components in the present example at least partly abut one another so as to clamp a line 27 for H₂O and 28 for H₂. Further lines connected to the outlets 18, 18′ lie outside the plane of the drawings and are not shown here.

FIG. 1B is a plan view of one of the bipolar plates 2 from FIG. 1A. In the example shown, the bipolar plate has a circular flow field 9 formed from a multiplicity of conductor structures, which are configured here as linear channel embossings 10 and ridges 10′ extending therebetween. The flow field 9 can also have a polygonal, for example a rectangular or hexagonal, shape. The channel embossings can be formed in a non-linear manner, for example in a coiled manner. They can each be configured to be continuous, as in the present example, but they can also be composed of different embossed elements arranged one behind the other. In the present case, the bipolar plate 2 also has through-openings 11 for the bolt elements 6, and through-openings 7, 8, 8′, 8″ that communicate with the inlet and the outlets 17, 18, 18′, 18″ and form the lines 27, 28, etc.

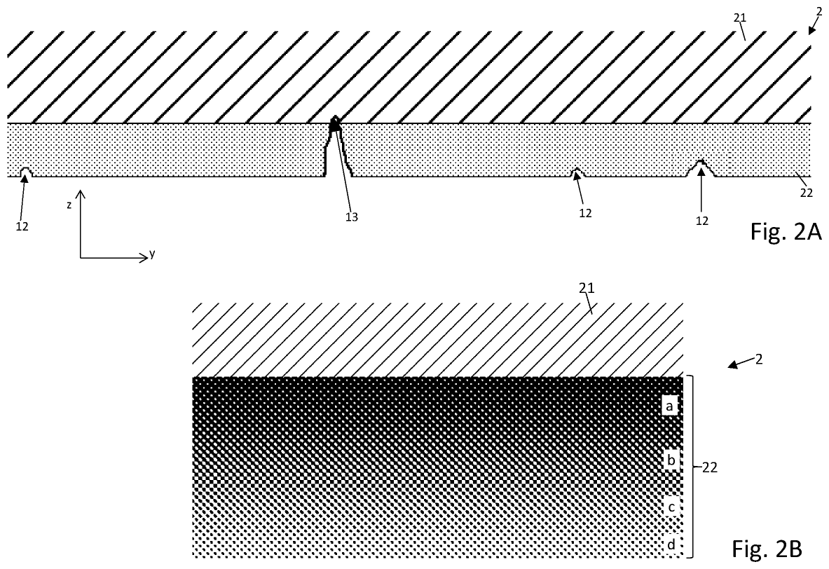

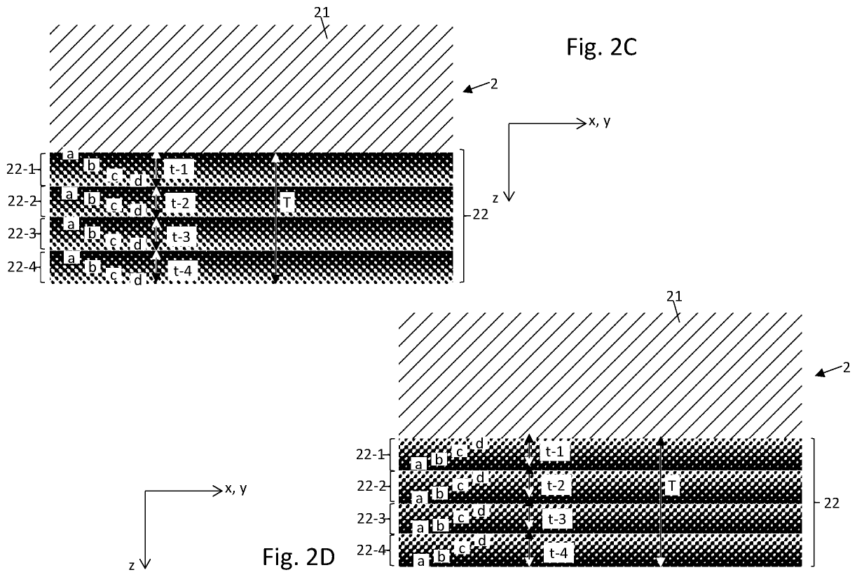

FIG. 2A is a sectional view of a bipolar plate 2 from the prior art having the broad damage thereto 12, 13. The bipolar plate 2 has a core layer 21 and a metal anti-corrosion layer 22 that protects the core layer 21 from corrosion. The different instances of damage 12, 13 are each shown to different extents. While the damage pattern of the damage 12 is limited to the anti-corrosion layer 22, the core layer 21 has already been compromised by the damage 13. It is important that the damage 12 cannot reduce the protective function of the anti-corrosion layer 22, for example by said anti-corrosion layer no longer being able to keep media away from the core layer 21, which can thus lead to further damage 13 to the core layer 21.

FIG. 2B is a sectional view of a bipolar plate 2 from the prior art having a global material density gradient over the entire anti-corrosion layer 22. In this case, different material densities are shown schematically as a raster gradient having regions rasterized to varying levels, of which, by way of example, four regions a, b, c, d are highlighted in the present case. In this regard, the material density shows monotonic and substantially continuous behavior over the entire thickness of the anti-corrosion layer 22, and in the present case decreases substantially continuously and monotonically as the distance from the core layer 21 increases, e.g. in the negative z-direction. This can be seen from the varying levels of rasterization; the average material density is thus greater in region a than in region b, greater in region b than in region c, and greater in region c than in region d.

FIG. 2C is a sectional view of a first example bipolar plate 2 having local material density gradients over individual anti-corrosion layer coats 22-1, 22-2, 22-3, 22-4 of the anti-corrosion layer 22. In this case too, different material densities are shown by varying levels of rasterization. As the distance from the core layer 21 increases, e.g. in the z-direction in this case, each of the anti-corrosion layer coats 22-1, 22-2, 22-3, 22-4 has a local material density gradient and accordingly a local raster gradient such that in this example too, in accordance with FIG. 2B, four regions a, b, c, d rasterized to varying levels are highlighted by way of example for each of the four anti-corrosion layer coats 22-1, 22-2, 22-3, 22-4 shown here by way of example. In this case, the respective thicknesses t-1, t-2, t-3, t-4 of the anti-corrosion layer coats 22-1, 22-2, 22-3, 22-4 can be identical or can vary from anti-corrosion layer coat 22-1, 22-2, 22-3, 22-4 to anti-corrosion layer coat 22-1, 22-2, 22-3, 22-4. The sum of the thicknesses t-1, t-2, t-3, t-4 of the anti-corrosion layer coats 22-1, 22-2, 22-3, 22-4 results in the layer thickness T of the anti-corrosion layer 22. In addition, the four regions a, b, c, d rasterized to varying levels can have the same material density in each anti-corrosion layer coat 22-1, 22-2, 22-3, 22-4, or have a material density that changes from anti-corrosion layer coat 22-1, 22-2, 22-3, 22-4 to anti-corrosion layer coat 22-1, 22-2, 22-3, 22-4. In the example shown, the material density within each anti-corrosion layer coat 22-1, 22-2, 22-3, 22-4, e.g. the local material density, decreases as the distance from the core layer 21 increases.

At each transition from anti-corrosion layer coat 22-1, 22-2, 22-3, 22-4 to anti-corrosion layer coat 22-1, 22-2, 22-3, 22-4, e.g. at the transition a-d from region a of one anti-corrosion layer coat 22-n to region d of the next anti-corrosion layer coat 22-(n+1) in the z-direction (here n=1 . . . 3), the material density changes abruptly in the present case. Accordingly, in the present case the material density at the transitions a-d thus has a gradient that actually runs in the opposite direction to the gradient within each anti-corrosion layer coat 22-1, 22-2, 22-3, 22-4. The gradient at the transitions d-a is greater in terms of magnitude than the gradient within one coat.

FIG. 2D is a sectional view of a second example bipolar plate having local material density gradients over individual anti-corrosion layer coats 22-1, 22-2, 22-3, 22-4 of the anti-corrosion layer 22. Once again, different material densities are shown by varying levels of rasterization. As the distance from the core layer 21 increases, e.g. in the z-direction in this case, each of the anti-corrosion layer coats 22-1, 22-2, 22-3, 22-4 likewise has a local material density gradient and accordingly a local raster gradient such that in this example, in accordance with FIGS. 2B and 2B, four regions a, b, c, d rasterized to varying levels are highlighted by way of example for each of the anti-corrosion layer coats 22-1, 22-2, 22-3, 22-4. Like before, in this case too, the respective thicknesses t-1, t-2, t-3, t-4 of the anti-corrosion layer coats 22-1, 22-2, 22-3, 22-4 can be identical or can vary from anti-corrosion layer coat 22-1, 22-2, 22-3, 22-4 to anti-corrosion layer coat 22-1, 22-2, 22-3, 22-4. In the example shown, the material density within each anti-corrosion layer coat 22-1, 22-2, 22-3, 22-4, e.g. the local material density, increases as the distance from the core layer 21 increases, by contrast with the bipolar plate 2 shown in FIG. 2C. In turn, the four regions a, b, c, d rasterized to varying levels can have the same material density in each anti-corrosion layer coat 22-1, 22-2, 22-3, 22-4, or have a material density that changes from anti-corrosion layer coat 22-1, 22-2, 22-3, 22-4 to anti-corrosion layer coat 22-1, 22-2, 22-3, 22-4.

The abrupt change in the material density occurs accordingly at the transitions a-d from region a of one anti-corrosion layer coat 22-n to region d of the next anti-corrosion layer coat 22-(n+1) in the z-direction (here n=1 . . . 3). Both in the example shown in FIG. 2C and in the example shown in FIG. 2D, the anti-corrosion layer coats 22-1, and thus the anti-corrosion layers 22, are attached directly to the core layer 21; in this case, therefore, the core layer 21 either does not have any coating or has a different protective coat. In this case too, the sum of the thicknesses t-1, t-2, t-3, t-4 of the anti-corrosion layer coats 22-1, 22-2, 22-3, 22-4 results in the layer thickness T of the anti-corrosion layer 22.

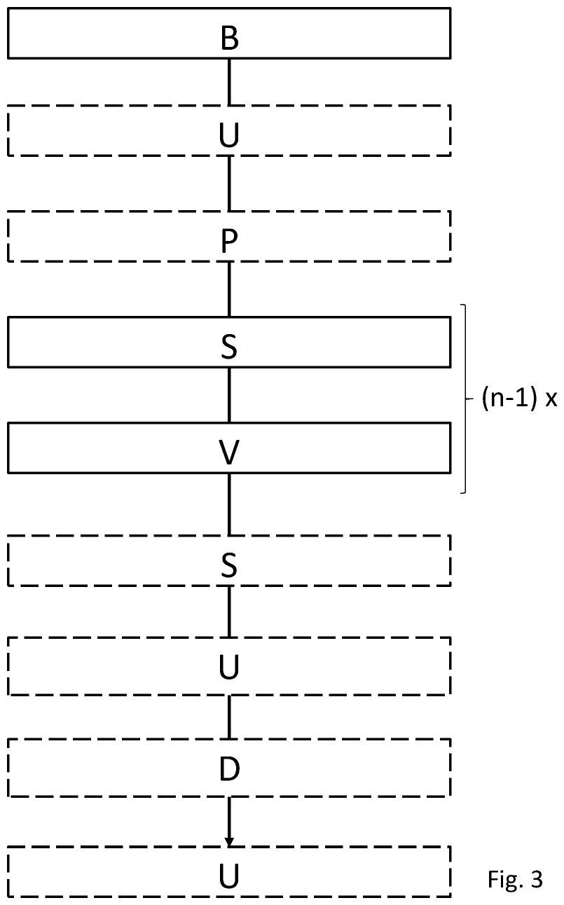

FIG. 3 is a flowchart of an example method for producing a bipolar plate 2 for an electrochemical system 1. In the example shown, the method comprises the method steps of providing B the core layer 21, deforming U the core layer 21, removing P the passive coat, sputtering (or cathode sputtering) S, compressing V by bombardment, and applying D a cover layer.

The compulsory method steps in this case are those of providing B the core layer 21 and (n−1) runs of the sputtering S, in each case followed by the compressing V. Accordingly, starting from the provided core layer 21 of the bipolar plate 2, which core layer consists of or comprises a a steel material, the bipolar plate (2) is coated (n−1) times with an anti-corrosion material using physical vapor deposition (sputtering S), an (n−1)th anti-corrosion layer coat 22-1, 22-2, 22-3, 22-4 being formed in the (n−1)th method step of sputtering S, where n>1, the anti-corrosion layer coat 22-1, 22-2, 22-3, 22-4 formed in each sputtering S being compressed V by bombardment with an inert gas in each case following the (n−1)th method step of sputtering S.

The other method steps in the method sequence shown in FIG. 3 are optional. Accordingly, the deforming U, in which conductor structures such as channels and ridges or ridge portions formed between the channels are molded in at least in some regions, and/or the removing P of the passive coat, in which the passive coat of the core layer is removed at least in some regions at least on the side to be coated, can be carried out after the providing and before the first sputtering S.

Thus, after the (n−1)th run of the sputtering S and compressing V, an additional sputtering S not followed by the compressing V can be carried out in accordance with the method sequence shown in FIG. 3. Independently of this additional sputtering S, the application D of the cover layer, during which a cover layer having a different composition from the anti-corrosion layer 22 is applied to the anti-corrosion layer 22, can likewise be carried out after the (n−1)th run of the sputtering S and compressing V. The method can be terminated with the further deforming U, which is shown as a method step after the application D of the cover layer as an alternative or additional method to the first deforming. In this step, the previous conductor structures can be supplemented, or new conductor structures can be molded in.

It is also possible to carry out a deforming step after the anti-corrosion layer 22 has been fully constructed but before the cover layer is applied D. This can constitute the sole deforming step for forming the bipolar plate 2, or it can be used to shape the conductor structures together with a deforming step immediately after the steel plate is provided.

FIGS. 1-2D are shown approximately to scale. FIGS. 1-2D show example configurations with relative positioning of the various components. If shown directly contacting each other, or directly coupled, then such elements may be referred to as directly contacting or directly coupled, respectively, at least in one example. Similarly, elements shown contiguous or adjacent to one another may be contiguous or adjacent to each other, respectively, at least in one example. As an example, components laying in face-sharing contact with each other may be referred to as in face-sharing contact. As another example, elements positioned apart from each other with only a space there-between and no other components may be referred to as such, in at least one example. As yet another example, elements shown above/below one another, at opposite sides to one another, or to the left/right of one another may be referred to as such, relative to one another. Further, as shown in the figures, a topmost element or point of element may be referred to as a “top” of the component and a bottommost element or point of the element may be referred to as a “bottom” of the component, in at least one example. As used herein, top/bottom, upper/lower, above/below, may be relative to a vertical axis of the figures and used to describe positioning of elements of the figures relative to one another. As such, elements shown above other elements are positioned vertically above the other elements, in one example. As yet another example, shapes of the elements depicted within the figures may be referred to as having those shapes (e.g., such as being circular, straight, planar, curved, rounded, chamfered, angled, or the like). Further, elements shown intersecting one another may be referred to as intersecting elements or intersecting one another, in at least one example. Further still, an element shown within another element or shown outside of another element may be referred as such, in one example.

It will be appreciated that the configurations and routines disclosed herein are exemplary in nature, and that these specific embodiments are not to be considered in a limiting sense, because numerous variations are possible. Moreover, unless explicitly stated to the contrary, the terms “first,” “second,” “third,” and the like are not intended to denote any order, position, quantity, or importance, but rather are used merely as labels to distinguish one element from another. The subject matter of the present disclosure includes all novel and non-obvious combinations and sub-combinations of the various systems and configurations, and other features, functions, and/or properties disclosed herein.

As used herein, the term “approximately” or “substantially” is construed to mean plus or minus five percent of the range unless otherwise specified.

The following claims particularly point out certain combinations and sub-combinations regarded as novel and non-obvious. These claims may refer to “an” element or “a first” element or the equivalent thereof. Such claims should be understood to include incorporation of one or more such elements, neither requiring nor excluding two or more such elements. Other combinations and sub-combinations of the disclosed features, functions, elements, and/or properties may be claimed through amendment of the present claims or through presentation of new claims in this or a related application. Such claims, whether broader, narrower, equal, or different in scope to the original claims, also are regarded as included within the subject matter of the present disclosure.

1. A bipolar plate for an electrochemical system, comprising a core layer, which comprises a steel material and a metal anti-corrosion layer that protects a core layer from corrosion,
wherein the anti-corrosion layer comprises a plurality of anti-corrosion layer coats that comprise a substantially identical anti-corrosion material and are arranged one on top of the other, a material density of the anti-corrosion material within an anti-corrosion layer coat having a gradient as the distance from the core layer increases.

2. The bipolar plate according to claim 1, wherein the material density of the anti-corrosion material within each of the anti-corrosion layer coats has a gradient as the distance from the core layer increases.

3. The bipolar plate according to claim 1, wherein the anti-corrosion layer coats have a minimum coat thickness of at least 20 nm.

4. The bipolar plate according to claim 1, wherein the anti-corrosion layer coats have a maximum coat thickness of at most 300 nm.

5. The bipolar plate according to claim 1, wherein the anti-corrosion layer has a minimum layer thickness of at least 50 nm.

6. The bipolar plate according to claim 1, wherein the anti-corrosion layer has a maximum layer thickness of at most 3 μm.

7. The bipolar plate according to claim 1, wherein the anti-corrosion material of the anti-corrosion layer is titanium or is substantially titanium or comprises titanium.

8. The bipolar plate according to claim 1, wherein the anti-corrosion layer is impermeable to a medium.

9. The bipolar plate according to claim 1, wherein the anti-corrosion layer is provided with a cover layer that is niobium, tantalum, platinum or gold or comprises niobium and/or tantalum and/or platinum and/or gold.

10. The bipolar plate according to claim 1, wherein the anti-corrosion layer is arranged only on a side of the core layer that faces the anode.

11. The bipolar plate according to claim 1, wherein the steel material of the core layer is a stainless steel or comprises stainless steel.

12. The bipolar plate according to claim 1, wherein the anti-corrosion layer is attached directly to the core layer.

13. An electrolyzer comprising at least one bipolar plate according to claim 1.

14. A method for producing a bipolar plate for an electrochemical system, comprising the following method steps:
starting from a core layer of the bipolar plate, which core layer comprises a steel material, coating the bipolar plate n times with an anti-corrosion material using physical vapor deposition, wherein an nth anti-corrosion layer coat is formed in the nth method step of coating, where n>1;
wherein at least following the (n−1)th method step of coating, the anti-corrosion layer coat formed during the relevant coating is in each case bombarded with an inert gas.

15. The method according to claim 14, wherein the anti-corrosion layer coat formed during the coating is also bombarded with an inert gas also after the nth method step of coating.

16. The method according to claim 14, wherein, before the first coating of the core layer, the passive coat of the core layer is removed at least in some portions at least on the side to be coated.

17. The method according to claim 14, wherein each coating is carried out using cathode sputtering.

18. The method according to claim 14, wherein the inert gas is argon or comprises argon.

19. The method according to claim 14, wherein before the nth coating, the core layer is deformed such that the nth coating proceeds from a deformed core layer and the core layer comprises, at least in some regions, conductor structures such as channels and ridges or ridge portions formed between the channels.
